(19) United States
(12) Patent Application Publication
(10) Pub. No.: US 2016/0237591 A1
(43) Pub. Date: Aug. 18, 2016

(54) GROUP IV NANOWIRES GROWN FROM INDUCTIVELY OR RESISTIVELY HEATED SUBSTRATES

(71) Applicant: CORNELL UNIVERSITY, Ithaca, NY (US)

(72) Inventors: Tobias HANRATH, Ithaca, NY (US); Benjamin T. RICHARDS, Ithaca, NY (US)

(21) Appl. No.: 15/027,566

(22) PCT Filed: Oct. 13, 2014
(86) PCT No.: PCT/US2014/060281

§ 371 Date: Apr. 6, 2016

Related U.S. Application Data
(60) Provisional application No. 61/889,745, filed on Oct. 11, 2013.

(51) Int. Cl. C30B 23/06; C23C 18/12; B22F 1/00; B22F 1/02; C25D 3/38; C25D 7/06; C30B 7/12; C30B 7/14; C30B 25/10; C30B 30/02; C30B 29/62; C30B 29/06; C30B 29/08; C30B 29/52; C30B 29/02; C23C 14/16

(52) U.S. Cl. CPC C30B 23/063; C23C 14/16; C23C 18/1204; C23C 18/1241; C23C 18/1291; C23C 18/1262; B22F 1/0025; B22F 1/025; C25D 3/38; C25D 7/0614; C30B 7/12; C30B 7/14; C30B 25/10; C30B 30/02; C30B 29/62; C30B 29/06; C30B 29/08; C30B 29/52; C30B 29/02; C23C 14/562

(57) ABSTRACT

Growth of Group IV nanowires with a substrate and a Group IV metalloid is performed using resistive or inductive heating of the substrate. A roll-to-roll process enables a metal surface to move through a reaction environment while reacting with a stream or bath of precursor to form the nanowire-metal complex. The Group IV nanowires on a surface of the substrate can have a surface loading greater than 10 mg/cm².

### CROSS-REFERENCE TO RELATED APPLICATIONS

This application claims priority to the provisional patent application assigned U.S. App. No. 61/889,745 and filed Oct. 11, 2013, the disclosure of which is hereby incorporated by reference.

### STATEMENT REGARDING FEDERALLY-SPONSORED RESEARCH OR DEVELOPMENT

This invention was made with government support under Grant Number DE-FG02-87ER45298 awarded by the Department of Energy. The government has certain rights in the invention.

### FIELD OF THE DISCLOSURE

This disclosure relates to Group IV nanowires and, more particularly, to a method of making Group IV nanowires.

### BACKGROUND OF THE DISCLOSURE

Nanowires have the potential to be the base material for a broad range of next-generation applications. Their one-dimensional structure gives rise to many unique physical, optical and electrical characteristics that can be applied to a broad spectrum of applications such as, for example, transistors, fuel cells, water splitting, stealth applications, Li-ion batteries, supercapacitors, cooling applications, biological sensors, or solar cells. Among the various nanowire compositions that have been achieved, Group IV metalloids, including Si and Ge, are well suited for technological applications. Many synthesis methods can produce high-quality nanowires with precise control over length and diameter. However, most synthesis methods cannot be realized at a commercially significant scale (i.e., greater than kg/day).

Today's high throughput methods are solution-based and are performed with noble metal seeds. This method produces commercially significant yields of nanowires, but commercial production of the noble metal seeds, extraction of the nanowires, and post-processing cause complications. In addition, to be utilized in applications the nanowires require polymer binders, chemical linking, or unique growth conditions to be attached to an electrically-conductive surface. The current methods of attachment are sub-optimal and hinder nanowire performance. Furthermore, the entire environment surrounding the nanowires is heated in the typical nanowire reactions. This causes unnecessary heating of the reaction fluid that is not in contact with the surface, which wastes heat and precursor. In addition heating the entire environment results in no discrimination as to where the nanowire reaction occurs, so patterned growth is difficult or even impossible.

Therefore, improved nanowire growth is needed. More particularly, nanowire production that is capable of producing commercially significant quantities of nanowires that are attached to a substrate is needed.

### BRIEF SUMMARY OF THE DISCLOSURE

In this disclosure, a method utilizing the conductive properties of the substrate as a heat source via resistive or inductive heating to improve nanowire growth is provided. Resistively or inductively heating a bulk metal substrate incorporated in a roll-to-roll process enables a reaction with a metal surface. Resistive or inductive heating can be used to grow crystalline Group IV metal nanowires comprising: 1) a substrate, specifically any metal or metal alloy that produces a solid-state compound with Si or Ge and 2) a Group IV metalloid precursor, which provides the growth of crystalline Group IV nanowires in a positive or atmospheric pressure environment. The residence time, temperature, precursor profile, precursor concentration, or surface patterning can be varied to rapidly produce a large quantity of high quality nanowires. Custom geometries may be used to adapt this process to many application spaces. Processing time can be reduced by, for example, at least a factor of ten by eliminating pump down and long reaction times. Expensive processing equipment used in competing methods, such as vacuum pumps, low pressure chambers, noble metal seeds, batch reactions, and hand extraction, can be avoided. Semi-batch or continuous roll-to-roll processing is possible. A material for the anode component in a lithium ion battery can be produced. The attachment of different functional groups to the nanowires surfaces can enable a variety of applications. Other advantages are provided including, for example, enabling localized heating, enhanced patternability, efficient precursor delivery, higher yields, and faster start-up times while depositing thin metal films for nanowire attachment, treating the surface of the nanowires, and processing using roll-to-roll technology.

An apparatus to produce the nanowires is also disclosed. The apparatus provides a versatile process for producing nanowires for various applications, including, for example, various routes for producing nanowires with multiple sources of metal growth material, an option for surface treatment, and an option for nanowire surface treatment with passivation layers or functional groups.

In one aspect, a flexible substrate is exposed to a Group IV precursor. This may occur during a roll-to-roll process. The substrate is resistively or inductively heated during the exposing such that a plurality of Group IV nanowires grow on a surface of the substrate. The substrate is resistively heated by passing a current through the substrate. The substrate is inductively heated by inducing a current in the substrate. The substrate is at a temperature from 200° C. to 800° C. during the heating. Secondary convective heating also can be provided around the substrate during the inductive or resistive heating. The exposure to the Group IV precursors may occur at substantially atmospheric pressure.

The nanowires can be composed of Si, Ge, or a combination thereof. The substrate can be a sheet, a foil, or a wire and can comprise a metal, a ceramic, a polymer, a fiber, or a composite. For inductive heating, the substrate can be a metal or magnetic foil. The surface of the substrate can be Cu, Ni, Cr, Mn, Ti, Fe, Co, Pd, or Pt.

Inductive or resistive heating of the substrate also can be used to dry the substrate after exposure to the Group IV precursor. Growth of the Group IV nanowires can be carried out such that a pattern of the Group IV nanowires on less than an entirety of a surface of the substrate is produced. The Group IV nanowires also can be functionalized or have a metal coating applied.

In another aspect, Group IV nanowires with a surface loading of greater than 10 mg/cm² are disposed on a surface of a flexible substrate. The Group IV nanowires can be composed of Si, Ge, or a combination thereof and can be arranged in a pattern on less than an entirety of the surface. The Group IV nanowires can be between 5 nm and 100 nm in a first dimension and can be greater than 100 μm in a second dimension perpendicular to the first dimension. The substrate can be a metal, a ceramic, a polymer, a fiber, or a composite and the surface of the substrate can be Cu, Ni, Cr, Mn, Ti, Fe, Co, Pd, or Pt. The Group IV nanowires may be functionalized or have a metal coating applied.

In an example, the substrate has a growth layer disposed on a heating layer. The growth layer can be copper and the heating layer can be Nichrome or magnetic stainless steel.

In another example, a metal layer is disposed on the Group IV nanowires and a second plurality of Group IV nanowires are disposed on the metal layer.

In another aspect, an apparatus includes a reactor chamber configured for roll-to-roll processing of a flexible, conductive substrate, a Group IV precursor supply connected to the reactor chamber, and a heating system configured to resistively heat or inductively heat the substrate. The substrate is resistively heated by passing a current through the substrate. The substrate is inductively heated by inducing a current in the substrate.

### DESCRIPTION OF THE DRAWINGS

For a fuller understanding of the nature and objects of the disclosure, reference should be made to the following detailed description taken in conjunction with the accompanying drawings.

FIG. 1. Shows the robust nature of the growth mechanism and the many geometries from which nanowires grow. The nanowires in FIG. 1 are germanium.

FIG. 2. A demonstration of Si and Ge nanowires grown from the bulk nucleated VSS growth mechanism.

FIG. 3. A rendering and schematic of the growth process in a liquid bath embodiment. All dimensions are in inches.

FIG. 4. Shows an embodiment of this process where another metal layer is utilized just for heating purposes, rather than growth.

FIG. 5. Shows that a layer by layer process can be utilized to get multiple nanowire layers with additional metal layers.

FIG. 6. Demonstrates that Si—Ge alloy nanowires can be produced from the bulk nucleated VSS growth mechanism.

FIG. 7. Examples of the rollers used in this process.

FIG. 8a. An example of a patterned growth surface that could be used for a pixel of a solar cell or LED.

FIG. 8b. Another example of a patterned growth surface that may be used for a thermoelectric device.

FIG. 9. An example of patterned growth surfaces that use localized heating to have selective growth on different areas by running multiple passes on different tracks of devices.

FIG. 10. Proof of concept pattern used to analyze the correct conditions for growth.

FIG. 11. Product of a proof of concept reaction demonstrating that Si nanowires may be grown with trisilane in a liquid medium.

FIG. 12. Product of a proof of concept reaction demonstrating that Ge nanowires may be grown with diphenyl germane in a liquid medium.

FIG. 13. Product of a proof of concept reaction that demonstrates Si nanowires may be grown with the vapor pressure of trisilane in a gaseous nitrogen environment.

FIG. 14. Test apparatuses used for non-pyrophoric (left) and pyrophoric (right) systems.

FIG. 15. 430 grade stainless steel with electrodeposited Cu. Note the thick coating of copper, but lack of uniformity in Cu coating.

FIG. 16. Ge nanowires grown from electrodeposited Cu on 430 grade stainless steel. FIG. 16a and FIG. 16c show low magnification images of the growth surface in the liquid and vapor phase, respectively. FIG. 16b and FIG. 16d contrast the nanowire morphologies grown in the liquid and vapor phase, respectively.

FIG. 17. The normalized change in resistance versus the change in temperature from the initial value (20.4° C.). The slope of this graph is the temperature coefficient of resistance.

FIG. 18. The predicted temperature profiles based on the temperature coefficient of resistance. In the 60 A case, stainless steel undergoes changes to its microstructure. This high temperature alteration will cause a non-linear transient change in resistance.

FIG. 19. A parameter study of Si nanowire product, grown in a gas phase reaction, comparing growth quality with varying inductive heating current and phenylsilane concentrations.

FIG. 20. A parameter study of Ge nanowire product comparing growth quality with varying inductive heating current and diphenylgermane concentrations.

FIG. 21. A parameter study of Si nanowire product, grown in a gas phase reaction, comparing growth quality with varying reaction time.

FIG. 22. A parameter study Ge nanowire product comparing growth quality with varying reaction time and growth phase.

### DETAILED DESCRIPTION OF THE DISCLOSURE

Although this disclosure will be described in terms of certain embodiments, other embodiments, including embodiments that do not provide all of the benefits and features set forth herein, are also within the scope of this disclosure. Various structural, logical, process step, and electronic changes may be made without departing from the spirit or scope of the disclosure. Accordingly, the scope of the disclosure is defined only by reference to the appended claims.

Growth of crystalline Group IV nanowire composites is performed using, for example, a bulk metal catalyst (e.g., a metal-containing surface of a substrate) and a vapor or liquid Group IV metalloid precursor using resistive or inductive heating of the substrate. The use of vapor flows allows for non-pressure-rated materials. Parameters such as, for example, growth height, nanowire diameter, and nanowire prevalence can be modified by conditions such as, for example, the residence time, temperature, precursor profile, precursor concentration, or surface patterning.

Macroscopic contact with the nanowires, which also may be referred to as nanowiskers, nanofilaments, nanorods, or tenticular filaments, has been a challenge of scaling supercritical fluid-liquid-solid (SFLS) nanowires, specifically with respect to extraction. To meet this challenge, a growth mechanism that produces nanowires attached to a surface is implemented. The metals that the nanowires are grown from create a macroscopic contact to the surface. The versatility of this reaction allows nanowires to be grown from any geometry and many different metals. The capability to grow from different metals allows for additional flexibility to customize preferred materials for different devices. For example, nanowires can be grown on Cu, Ni, Cr, Al, Au, Ag, or alloys thereof.

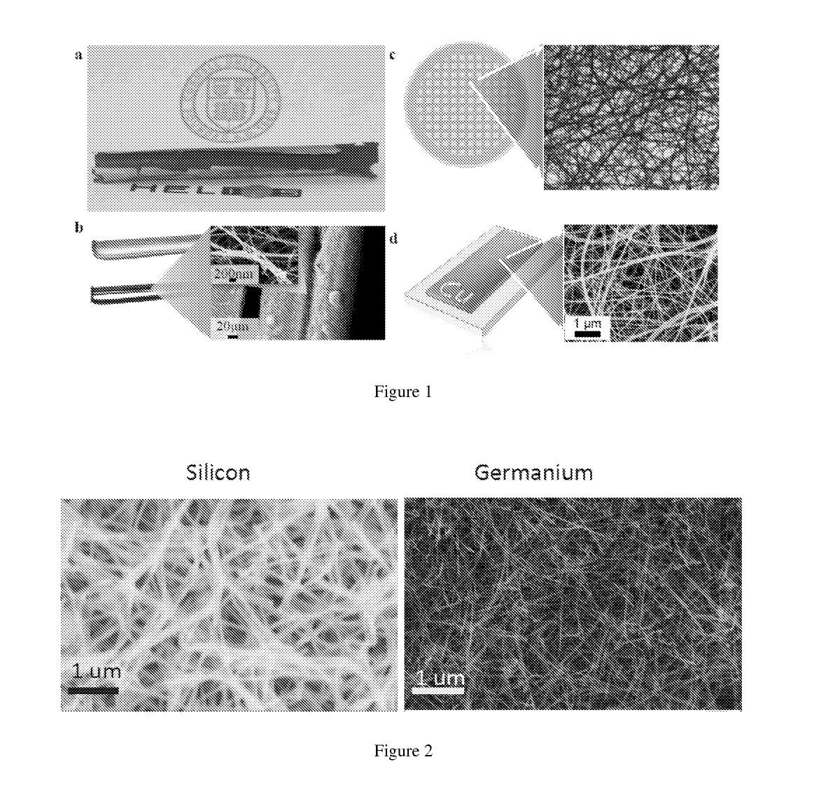

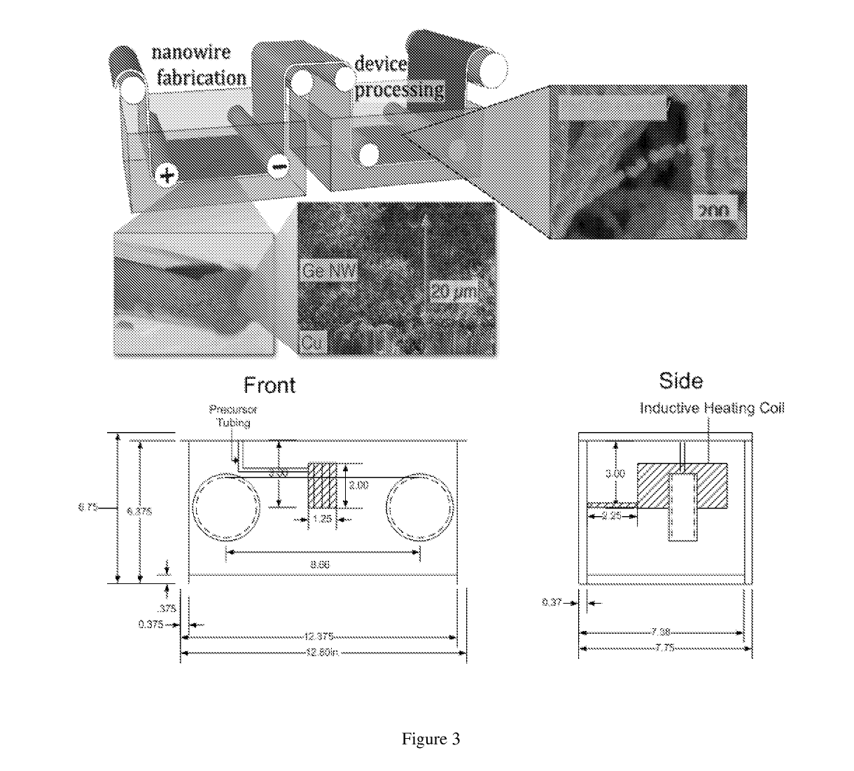

Methods are provided for growth of at least partially crystalline or crystalline Group IV nanowires utilizing a bulk metal catalyst and a Group IV metalloid with heat provided via resistive or inductive heating. The process is a roll-to-roll process in which a metal surface of the substrate moves continuously through a reaction environment while continuously reacting with a stream or bath of precursor to form the nanowire-metal complex. A supply of heat is required for the reaction to proceed. Temperature of the reaction can be controlled. To create a continuous system, a roll-to-roll process that incorporates resistive or inductive heating is used to provide localized heat in a fluid (herein referring to liquid or gas) environment. This enables a bulk nucleated solid state reaction to occur and proceed to nanowire growth. FIG. 1 demonstrates the versatility of geometries of the grown nanowires. FIG. 2 shows that both Si and Ge nanowires may be grown from the surface. See FIG. 3 for a graphical rendering and schematic of a process that uses the techniques described herein.

In an embodiment, a flexible, conductive substrate is exposed to a Group IV precursor during a roll-to-roll process. By flexible, the substrate has properties enabling it to be processed in a roll-to-roll apparatus, bent over a roller, or wound in a spool or other storage device. The substrate is inductively or resistively heated during the exposing and Group IV nanowires are grown on the substrate. By resistively heated, a current passes through the substrate. By inductively heated, a current is induced in the substrate. The substrate is a primary source of heat during the exposing. By primary, it is meant that the majority of heat produced in the reactor chamber originates or radiates from the substrate. The substrate is heated directly and heating is concentrated to the substrate as opposed to indirectly heating an entire reactor chamber to heat the substrate. Inductive or resistive heating of the substrate may be performed with or without indirect, secondary heating. Thus, inductive or resistive heating of the substrate may be the only form of heating used during the nanowire growth. Convection from, for example, heaters in the reactor chamber may be used as an indirect, secondary heat source of the substrate. For example, lamps or heaters in the wall of the reactor chamber can be used as indirect, secondary heat sources.

Without intending to be bound by a particular theory, a thermal boundary layer develops near the surface of the resistively heated or inductively heated substrate. The temperature is generally constant within the boundary layer, but drops off outside the boundary layer. The nanowires may be shorter than this boundary layer. In an example, the nanowires grow within this boundary layer.

The Group IV nanowires grown on the flexible, conductive substrate comprise one or more Group IV elements, which may be Si or Ge. In an example, only Group IV elements may be included in the Group IV nanowires. In another example, other elements may be included with one or more Group IV elements in the Group IV nanowires. In an example, the Group IV nanowires can attain surface loading greater than 10 mg/cm². Nanowire growth density achieved through resistive or inductive heating of the substrate unexpectedly surpassed densities of conventional chemical vapor deposition methods.

The Group IV nanowires may be between 5 nm and 100 nm in a first dimension and are greater than 100 μm in a second dimension perpendicular to the included first dimension. The first dimension may be a width or diameter and the second dimension may be a length. The second dimension may not be parallel to a plane of the surface of the substrate where the Group IV nanowires are grown. Nanowires may fall across a surface of the substrate.

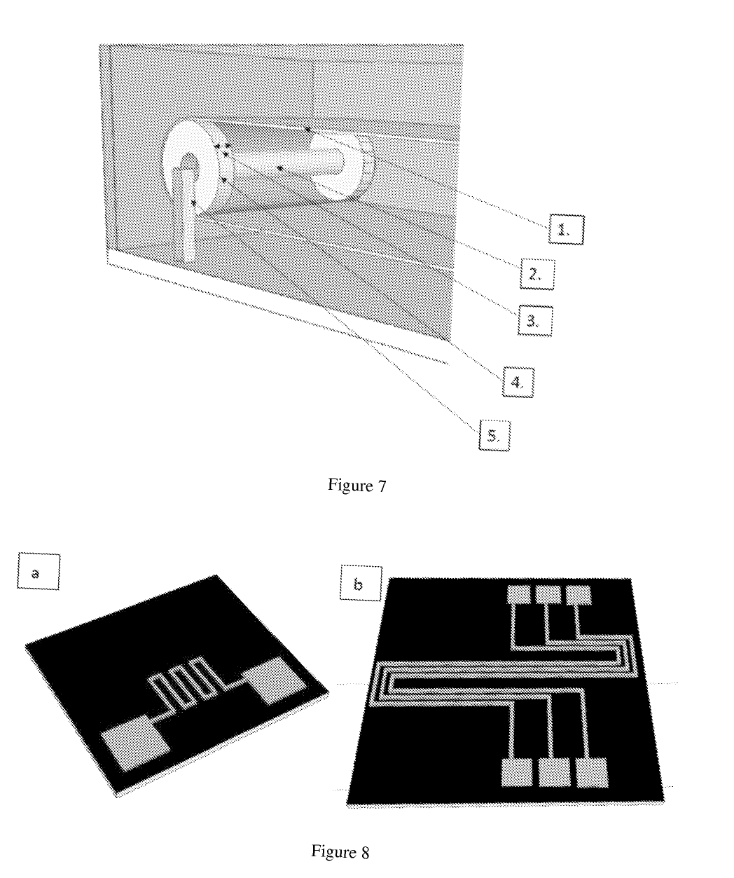

In another embodiment, an apparatus is used to grow the Group IV nanowires, as seen in FIGS. 3 and 7. The apparatus has a reactor chamber configured for roll-to-roll processing of a flexible, conductive substrate. The apparatus also has a Group IV precursor supply connected to the reactor chamber through the precursor tubing and a heating system configured to heat the substrate (e.g., the inductive heating coil in FIG. 3 or resistive heating through the rollers in FIG. 7). The substrate is a source of heat in the reactor chamber. Resistive or inductive heating systems may be used to heat the substrate.

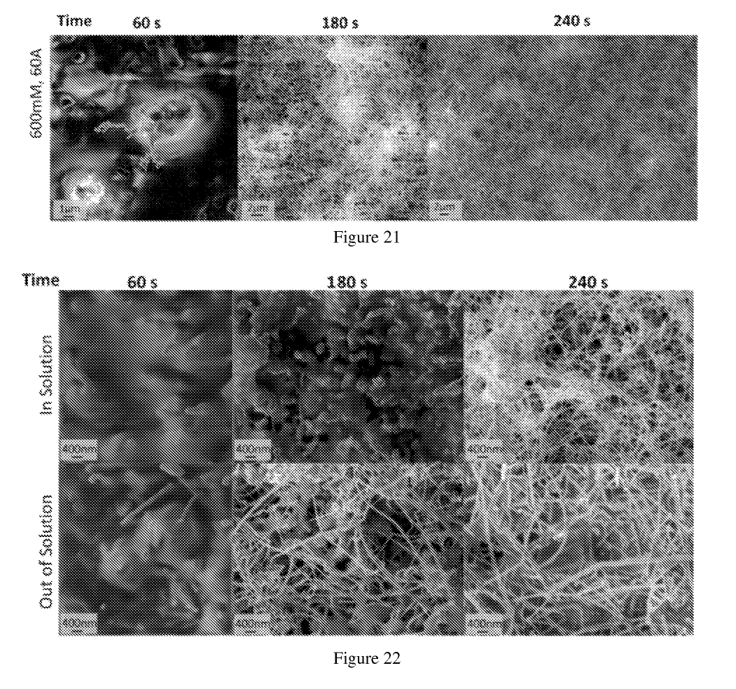

Roll-to-roll processing provides, for example, production speed and scalability. The production speed is typically governed by the slowest step in the process, in this case the nanowire reaction. Reaction time (or residence time) can be adjusted by the size of the reactor chamber, area of exposure to the precursors, precursor concentration, or the speed of the substrate. Ge nanowire growth may be faster than Si nanowire growth in some instances. It has been observed that reactions vary between seconds to minutes, depending on which precursors are used and the conditions of the reaction. This creates nanowires on a substrate available for various applications. The reaction time may be only a few seconds. In one example, the reaction time is approximately 10 seconds. Length of the reaction time can affect morphology of the nanowires. A longer nanowire may be produced from a longer reaction time, as seen in FIG. 21 or FIG. 22.

The use of vapor flows allows for non-pressure-rated materials, such as Plexiglas, to be used in the reaction chamber. If induction heating is used, the reaction chamber may be fabricated of non-magnetic materials to prevent alteration of the direction of the magnetic field.

The growth height, nanowire diameter, and nanowire prevalence can be modified by the residence time, temperature, precursor profile, precursor concentration, or surface patterning. For example, longer reaction time can result in longer nanowires and can encourage additional nucleation at the surface of the substrate. In another example, nanowire diameter can increase with temperature. In yet another example, surface patterning such as physically or chemically roughening the substrate, can provide additional nucleation sites and increase prevalence of nanowires. The reactor allows the characteristics of the nanowire growth to be varied by changing the reaction parameters. The synthesis produces high yields of at least partially crystalline or crystalline nanowires with a low concentration of metal impurities that are epitaxially attached to a bulk conductive surface. The continuous and semi-batch processes utilized in this roll-to-roll reactor produces nanowires more efficiently and can prepare nanowires to be used in a downstream process or to be transported.

The nanowire alignment and straightening may occur using specialized drying techniques. Surface annealing through resistive or inductive heating can evaporate solvent from the surface of the substrate, such as after exposure to the precursor. Solvent-rich gas streams can be condensed by a cold finger, collected, and recycled. Gas streams also can be used to blow solvent from the surface of the substrate. These gas streams can align nanowires in a direction parallel to the stream.

A nanowire is a one-dimensional growth of a crystalline material. This nanowire is typically composed of an electronically conductive material core. The surface can be an amorphous material. Although the size characteristics are variable, these materials are physically characterized as one dimensional because in two dimensions (x, y) the nanowires are characterized between 5 nm-100 nm, including all values in between, which are very small in relation to the length. In the third dimension, the length, the nanowires are greater than 5 um. Typically, the aspect ratio is greater than 100 (length:diameter).

The population length and diameter of the nanowire can be estimated by measuring a statistically significant sample of the population For example, the sample may be approximately 100 to 200 nanowires in a 60 mg batch. Although different lengths are desirable for different applications, typically a narrow distribution of the length and diameter is a desirable characteristic and can simplify device reproducibility. Other distributions may be desired for other applications. Nanowire layer height can be adjusted, as seen in FIG. 3. This indicates the amount of nanowires that can be attached to a given surface area. The nanowire packing is dependent on the reaction parameters.

A pattern of the Group IV nanowires on less than an entirety of a surface of the substrate can be grown. The pattern may suit a particular application. Nanowires can be patterned by depositing masked metal vapor onto a surface or nanowires could be grown in select orientations to be used as transistors on a chip. A mask is placed in contact with or in close proximity to the surface of the substrate. This mask may be, for example, a hard mask, photoresist, shadow mask, or stencil mask. Lithography may be used for small feature sizes, such as though less than 80 μm. A lithographic process can include priming the substrate surface, applying a layer of photoresist, exposing the photoresist through a mask, developing the photoresist, and depositing metal at the surface. Contact patterning also can be used.

Nanowires have electronic, light, and electrochemical applications. These materials can be used in, for example, field effect transistors, photovoltaic solar cells, light-emitting diodes, batteries, biological-sensors, cooling applications, or other devices.

For example, nanowires directly grown from copper foil may be directly integrated as an anode or other electrode material in Li-ion batteries. The theoretical maximum charge capacity per weight of this type of battery would be over 10 times greater than today's current anode material. This roll of material may then be laminated with a polymer separator followed by contact with a cathode material to create a battery.

The highest cost of production may be the cost of the precursor. In the working examples organometalloid precursors and trisilane were tested. In these reactions metalloid hydrides are produced and react at the surface. Metalloid hydrides such as, for example, silane and germane, also may be used to produce nanowires. Typically, research quantities of nanowires based on research quantities of organometalloid precursors cost too much to be marketed for most nanowire applications. However, pure metalloid hydride precursor bought in commercial quantities, for example, silane or trisilane, produces nanowires less than a hundredth the cost per gram of the research quantities. This creates a cost competitive material for production.

Reaction Details

The embodiments disclosed herein are compatible with liquid and gas phase reactions. This versatility is an advantage from other reaction systems. The reaction and activation may be performed in an inert gas environment. Gas/vapor phase processes can be technologically simpler and more uniform than liquid phase reactions. Reactions in gas phase can be performed with either pure precursor gas or a mixture of precursor gas/vapor and inert carrier gas. Liquid processes may use a precursor solution bath, a surface wash station for solvent recovery and cleaning, and power to heat the solvent. Liquid phase reactions involve precursor that is either pure or dissolved in solvent.

Solvent selection may depend on the precursor. The solvent can be inert and miscible. Oxygen-containing solvents may be avoided if a reaction will occur with the metalloid precursor. Thus, the solvent may be an organic solvent without oxygen reduction groups. Typically, water is not used. High boiling point (e.g., squalene) and low boiling point solvents both can be used for precursor delivery. Squalene allows for the precursor to be vaporized, in high concentration, from the liquid stream. This can enable slow reaction kinetics. Low boiling point solvents allow the entire solution to be vaporized. This assists during solvent removal.

The embodiments disclosed herein provide compatibility with a variety of substrate materials. These include, but are not limited to metals, ceramics, polymers, fibers, and composites. The substrate material has properties enabling it to withstand the mechanical and thermal stresses of roll-to-roll processes and nanowire growth. These mechanical stresses include tensile forces that the web material is subjected to. For inductive heating, the substrate should exhibit effective coupling with inductive heating coil. These materials, include, but are not limited to magnetic foils or metal films. Hard magnetic materials such as ferromagnetics like ferritic stainless steel, Fe, Co, or Ni or resistive metals such as Nichrome may be used as a substrate. In another embodiment, spool-to-spool processing can be utilized to produce nanowires grown from metal wires that are heated via resistive heating. Spool-to-spool processing is similar to roll-to-roll processing except a wire is used as a substrate instead of a larger foil or sheet. This may provide benefits to applications that are enabled by one-dimensional hierarchal structures. Additional geometric form factors can enable the nanowire devices to be used in specialized applications.

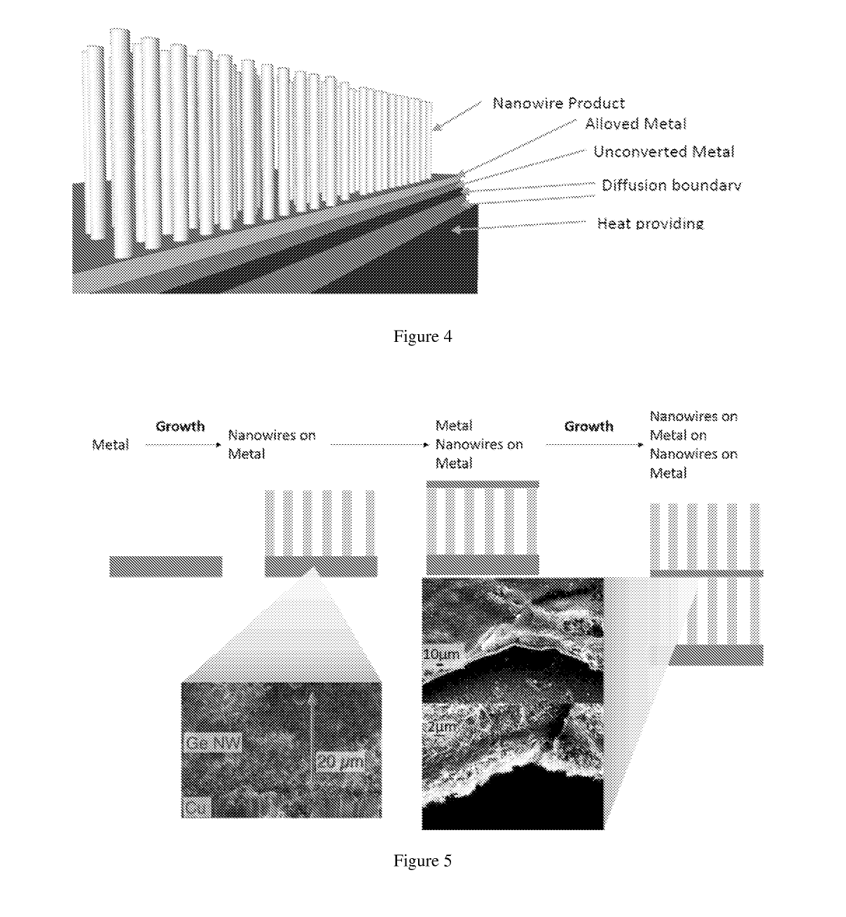

To decouple the requirements for heating and solid-state reaction at the metal surface, the substrate is comprised of a growth layer and a heating layer. In one embodiment, the growth layer and the heating layers may be separated, as seen in FIG. 4. Copper on Nichrome or copper on magnetic stainless steel are examples of the growth layer and heating layer.

For applications requiring high surface coverage of nanowires, the process of applying copper and growing nanowires can be performed via successive metal deposition and nanowire reactions. The working examples provide an example of this layer-by-layer growth technique. FIG. 5 illustrates an image of material from a cleaved cross section.

The reaction can be performed on both front and back sides of the metal surface. This increases the percentage of nanowire weight in the device.

Many different types of metals may be used as a growth surface on the substrate, which may be a growth layer. Potential metals for this type of growth typically form thermodynamically stable, sub-eutectic compounds. These metals include, but are not limited to, Cu, Ni, Cr, Mn, Ti, Fe, Co, Pd, or Pt, or alloys thereof. The purity of these metals can vary. The solid growth mechanism has the ability to grow from substrates of various shapes, including foils, wires, covered substrates (evaporation, sputter, or electroplating), or patterned substrates. The versatility of geometry allows for customization to different applications.

The precursors thermally decompose into metalloid hydrides. The metalloid hydrides are non-corrosive and have clean byproducts. Group IV metalloid hydride precursors maybe used for these syntheses.

The reaction may be performed with precursors that exhibit sufficient degradation rate for silicon, germanium, or other Group IV nanowires growth. Some examples of gaseous precursors include, but are not limited to, silane, disilane, germane, or combinations thereof. Some examples of liquid precursors include, but are not limited to, phenylsilane, diphenylsilane, trisilane, phenylgermane, diphenylgermane, digermane, trigermane, or combinations thereof. Other fast reacting precursors like the ones above also may be used.

Other examples of Group IV precursors that may be used independently or with other precursors include chlorosilanes, akylsilanes, arylsilanes, fluorosilanes, chlorogermanes, akylgermanes, arylgermanes, fluorogermanes, chlorostannanes, akylstannanes, arylstannes, fluorostannes, chloroplumane, akylplumane, arylplumane, and fluoroplumane. Other examples of Group IV hydride precursors that may be used independently or with other precursors include, but are not limited to, stannane, distannane, tristannane, plumane, diplumane, and triplumane.

Precursor concentration can be adjusted to affect surface coverage. Typical precursor concentrations in the reactor chamber are in the range of 200 mM to pure precursor for liquid phase reactions.

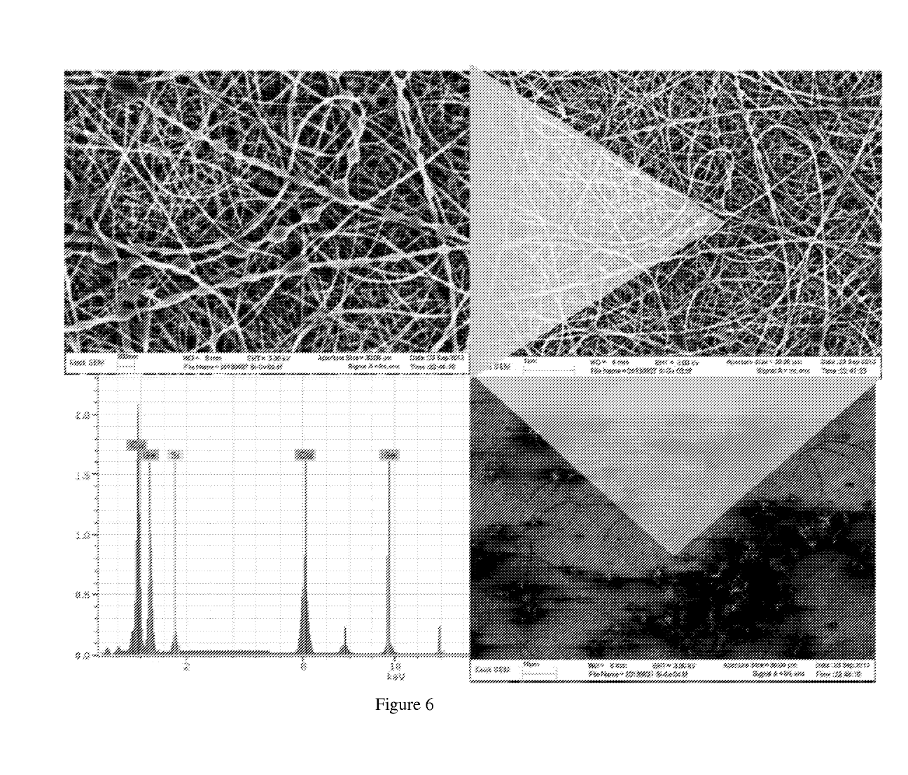

Alloys of Si and Ge are possible with an appropriate combination of Si and Ge precursors. Through the similarities of Si and Ge, this solid state growth process may produce Si—Ge alloy, as seen in FIG. 6. Alloyed nanowires created from a bulk nucleated vapor-solid-solid (VSS) growth mechanism are possible. Moreover, those skilled in the art will also be able to extend this approach to growth of other nanostructures formed by reaction at the metal surface. Alloy nanowires may have properties useful for various applications and may be important for property intensive devices.

The temperature range of the substrate for growth is between 200-800° C., including all ° C. values and ranges in between. This large temperature range follows the prediction for all thicknesses and useful metals exploited in nanowire-enabled devices. The particular temperature used for nanowire growth may depend on the precursor that is selected. For example, the temperature may be from approximately 300° C. to 450° C. or approximately 450° C. to 550° C., including all ° C. values and ranges therebetween.

Nanowires can be grown at substantially atmospheric pressures, including pressures of a supercritical fluid. The pressure can vary depending on desired properties or parameters of the nanowires. For example, the pressure may be approximately 14 to 17 psia. In another example, a pressure above atmospheric pressure can be used. In an example, substantially atmospheric pressure is less than 125% of atmospheric pressure, including all values and ranges in between.

Resistive and inductive heating of the substrate presents an efficient method to activate the reaction process. For example, the typical reactions with inductive and resistive heating have transients that require less than 10 seconds to reach 400° C.

A foil, rollable sheet metal, or wire of material that serves as a substrate is rolled through a reactor chamber beginning from a roll and ending on a roll. A motorized roller system transports the substrate. The system may use a serpentine path through the reactor chamber to increase residence time and decrease reactor costs. This may include a reactor chamber with multiple passes and baffles to direct precursor flow, which can increase the amount of time that the precursor is exposed to the substrate.

The reactor can run either with vapor or liquid precursors. Seals may be provided to contain the precursors in the reactor chamber.

The inside of the reactor may be fabricated of a material that does not participate in the nanowire reaction. For example, various glasses, silicon dioxide, and certain stainless steel alloys will not participate in the nanowire reaction.

A nozzle system may be used to direct the precursors, adjust a concentration of the precursor, or affect growth of the nanowires. The nozzle or nozzles can provide counter-current flow, parallel flow, or any angular flow therebetween.

The rollers have design considerations that improve the quality of the product of this system as seen in FIG. 7. The radius of the substrate or other web material is configured to potentially avoid plastic deformation (1). The center of the roll is protected from contact (2) to prevent detachment of the nanowire mesh. Contact at the bottom of the roller (3) is large enough to mitigate contact resistance (for resistive heating) between the contacts at the surface and the roller. The rollers are conductive (4) to deliver current to the substrate for resistive heating. Thus, the rollers can serve as electrodes. The rollers may have a conductivity of at least 10×10⁻¹⁰ Ω/m in one instance. The rollers are mounted (5) to enable rotation.

Depending on desired application of nanowire film the nanowires fabrication line may be directly integrated with additional downstream processes. These processes include, but are not limited to, straightening, drying, surface passivation, etching, doping, and functionalization.

Attaching different functional groups to the surface of the nanowires can affect the performance of a nanowire device. Functional groups also can be used to adapt the nanowires for different applications. Functional groups can include, for example, layers of S, C, organics, halogens, hydride, oxides, proteins, and nanowires. Methods of functionalization are known in the art. Metals can also be evaporated, chemically attached, or chemically reacted to the surface. For example a C layer has been shown to mitigate some of the stress of lithiation. A metal coating may be applied to a portion of the nanowire surfaces or all of the nanowire surfaces.

Chemical doping can be performed on the nanowires for various applications. The dopant can, for example, shift the energy level of the materials so that they can be tailored as a conductor in a layered solar cell. This can be performed in a post treatment process similar to surface passivation. Thermal deposition, electrochemical, or chemical processes can be used for surface passivation. In an example of thermal deposition passivation, Cu is evaporated onto the surface of the nanowire mesh to create a passivation layer. In an example of electrochemical passivation, the nanowire mesh is placed in an electrolyte and a potential placed between the nanowire mesh substrate and a counter electrode deposits a metal on the surface. In an example of chemical passivation, the surface of the nanowires undergoes a chemical reaction such as oxidation.

The nanowires may be removed from the substrate. For example, an ultrasonic horn can be used to fracture the nanowires. Alternatively, the nanowires may remain on the substrate for particular applications.

Another distinct advantage is that this growth mechanism will only proceed on growth metals that are heated. This allows selected growth areas or custom geometries. For example, the heating electrode can be structured to localize heat and pattern heating on the substrate (or a portion thereof). Some examples of selected growth are shown in FIGS. 8a and 8b. The custom geometries can also include different types of materials in a pattern (i.e., Ge, Si, alloys, doped).

### WORKING EXAMPLES

### Example 1

### Liquid Phase Reaction—Si

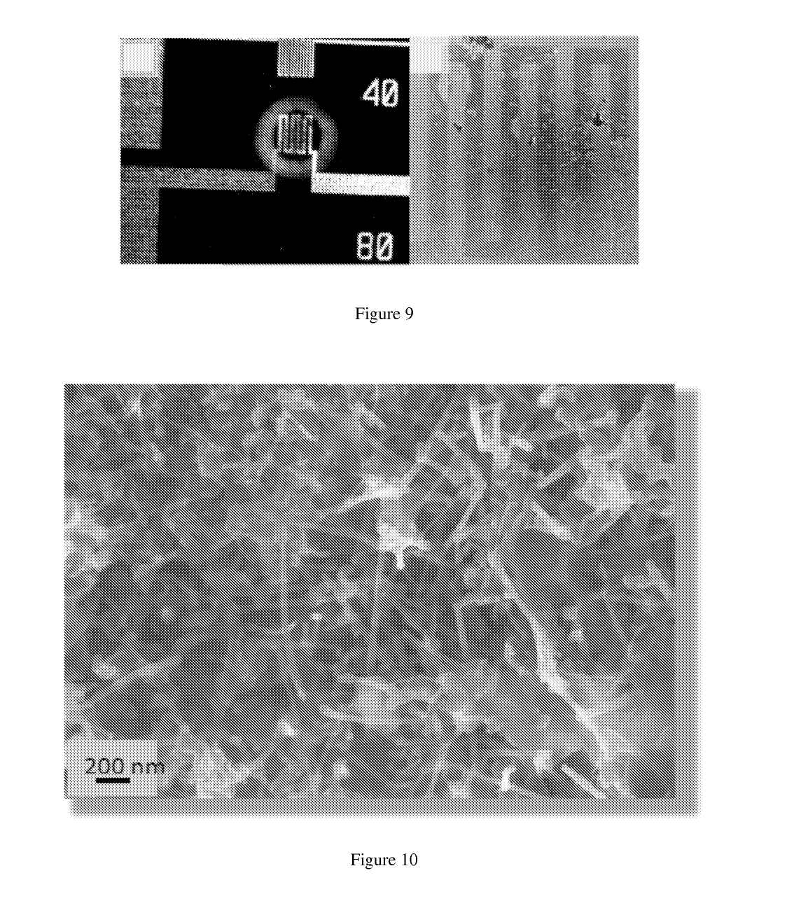

The patterned geometry (thickness of Cu 100 nm) in FIG. 9 was attached to a power supply and placed in a solution of 100 mM trisilane and squalene. The power supply provided 2.1*10⁷ W/m² of resistive heating. The reaction lasted seconds. This created the nanowires observed in FIG. 10.

### Example 2

### Liquid Phase Reaction—Ge

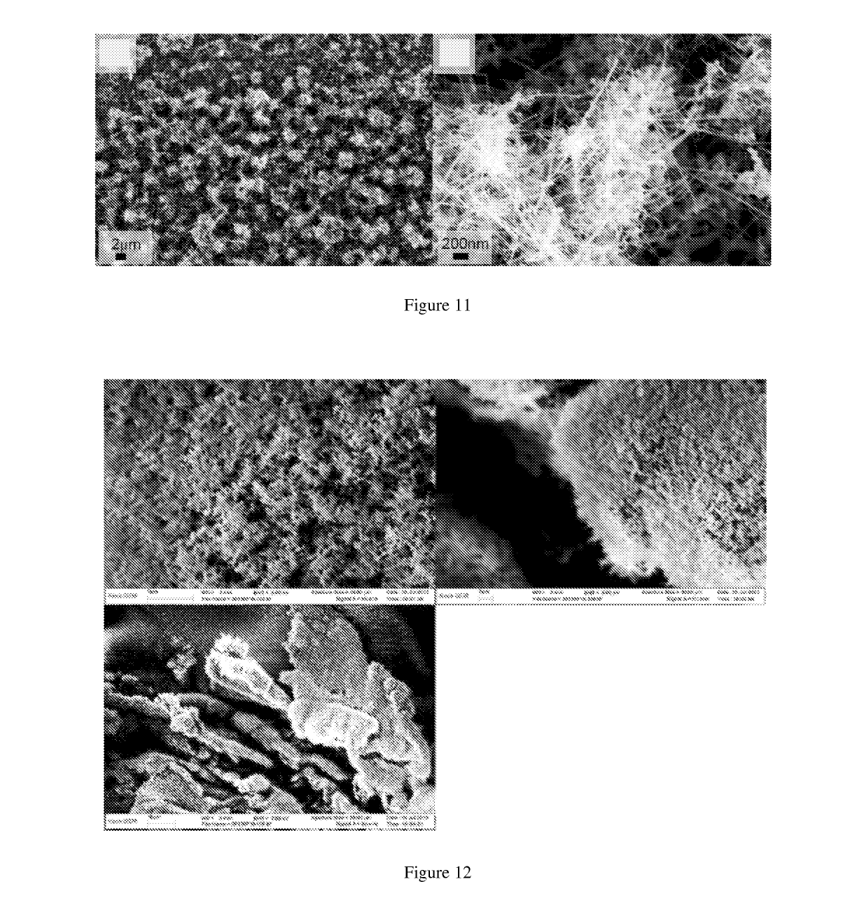

The patterned geometry (thickness of Cu 100 nm) in FIG. 10 above was attached to a power supply and placed in a solution of 100 mM diphenylgermane and squalene. The power supply provided 3*10⁷ W/m² of resistive heating. The reaction lasted 2.5 minutes. This created the nanowires observed in FIG. 11.

### Example 3

### Vapor Phase Reaction—Si

The patterned geometry (thickness of Cu 100 nm) in FIG. 9 was attached to a power supply and placed above 300 μl of trisilane in a nitrogen environment. The power supply provided 6*10⁶ W/m² of resistive heating. The reaction lasted ten seconds. This created the nanowires observed in FIG. 12. This, by extension, should be applicable to Ge nanowires.

### Example 4

### Wire Geometries

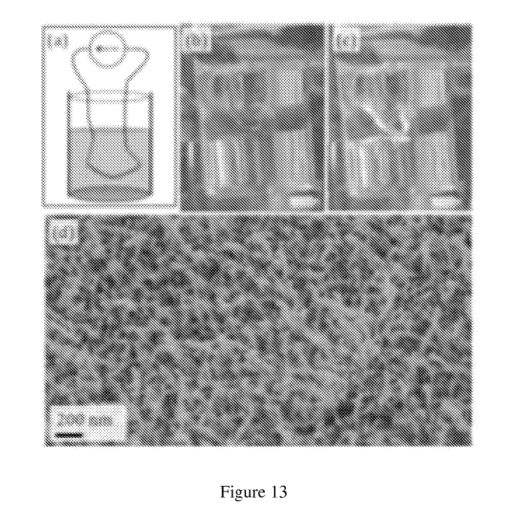

The patterned geometry (thickness of Cu 80 μm) in FIG. 13a was attached to a power supply and placed in a solution of 200 mM DPG and squalene. The power supply provided 2.3*10⁷ W/m² of resistive heating. The reaction lasted seconds. This created the nanowires observed in FIG. 13d.

### Example 5

### Multiple Growth Steps

Ge nanowires were grown from a piece of (4″×1″) Cu foil that was inserted in a 5 mL stainless steel reactor. A furnace that contained the reactor was preheated to 400° C. A 3.5 mL precursor solution of 1250 mM diphenylgermane in benzene was created in a nitrogen glovebox and transferred to an injection loop on the reaction apparatus. This was injected into the furnace at 5000 psig and remained for 7 minutes. Following the reaction the furnace was opened to cool and the pressure was released. The reactor was taken to the nitrogen glovebox where it was opened. The nanowires were recovered from the reactor and placed in a bell jar of a thermal evaporator. 5 nm of chromium was evaporated above the grown nanowires followed by 100 nm of copper. The reaction was run an additional time and nanowires grew from the new layer of Cu. This, by extension, should also work with a resistively heated process.

### Example 6

### Alloy Nanowires

Ge—Si alloy nanowires were grown from a piece of (4″×1″) Cu foil that was inserted in a 10 mL stainless steel reactor. A furnace that contained the reactor was preheated to 480° C. A 3.5 mL precursor solution of 583 mM phenylsilane and 375 mM diphenylgermane in benzene was created in a nitrogen glovebox and transferred to an injection loop on the reaction apparatus. This was injected into the furnace at 3500 psig and remained for 7 minutes. Following the reaction the furnace was opened to cool and the pressure was released. The reactor was taken to the nitrogen glovebox where it was opened. The nanowires were recovered from the reactor and placed in a bell jar of a thermal evaporator. 5 nm of Cr was evaporated above the grown nanowires followed by 100 nm of Cu. The reaction was run an additional time and nanowires grew from the new layer of Cu. This, by extension, should also work with a resistively heated process.

### Example 7

### Inductive Heating

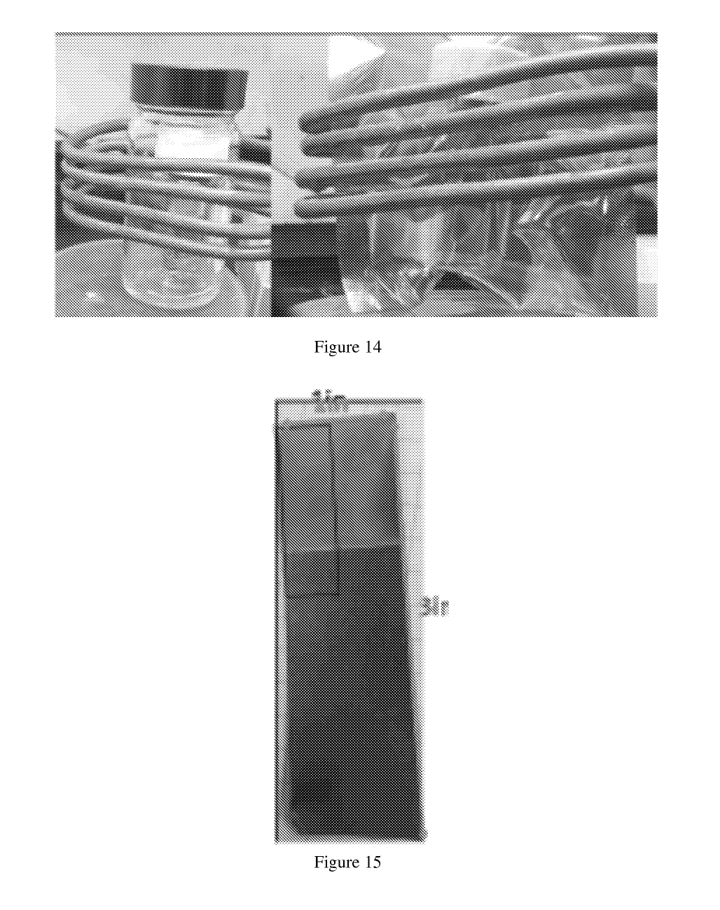

FIG. 14 illustrate two test apparatuses. In both test apparatuses, a 4 mL vial is placed inside a 20 mL vial with a 0.3″×1″ piece of 430 grade stainless steel submerged in a 3 mL precursor solution. This liquid level provides testing of both a liquid and vapor phase reactions. The apparatus on the left incorporates a large jar that accommodates the nested vials, which allows gases to escape the embedded jars without escaping the outside jar. This apparatus on the left is assembled in a nitrogen filled glove box brought to the inductive heater. The apparatus on the right performs the same function except the jar is replaced by a plastic bag which does not allow for exchange of oxygen. This can improve the safety of experiments utilizing pyrophoric precursors. A bubbler attachment can be made to release gas pressure on the plastic bag via a 16 gauge needle.

Two methods of metal deposition on magnetic foils have been performed. The first being thermal evaporation on metal films. The second being electrochemical deposition of copper on stainless steel. Using a 0.5M of copper sulfate in water, a film that is >100 nm can be electroplated in under a minute.

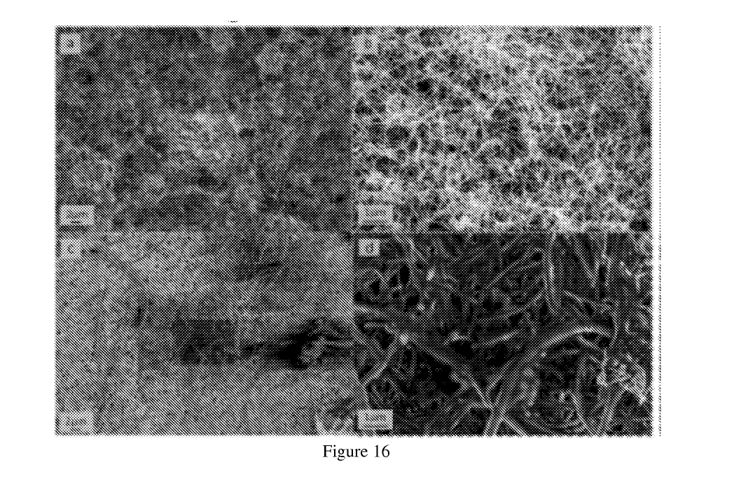

FIG. 15 shows a piece of electroplated 430 grade stainless steel that has electroplated Cu deposited on the surface. This method of deposition is adaptable to a roll-to-roll process. FIG. 16 shows Ge nanowires that were grown from the area in black in FIG. 15. Nanowire growth was not observed on the magnetic stainless steel.

Rapid annealing of magnetic films via coupling with alternate magnetic fields provides the necessary heat required to grow nanowires. Temperature may be controlled to scale this reaction method and deliver repeatable results. The inductive heating coil is used on a specific piece of 430 grade stainless steel that is contained inside a sequence of jars and bags.

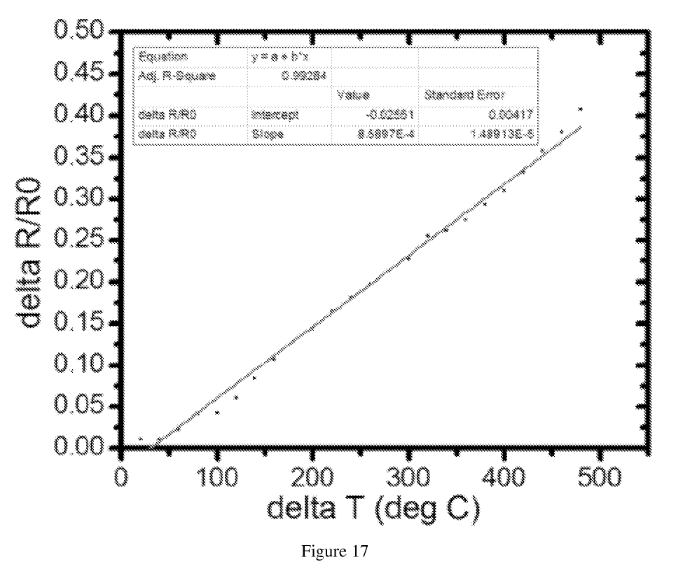

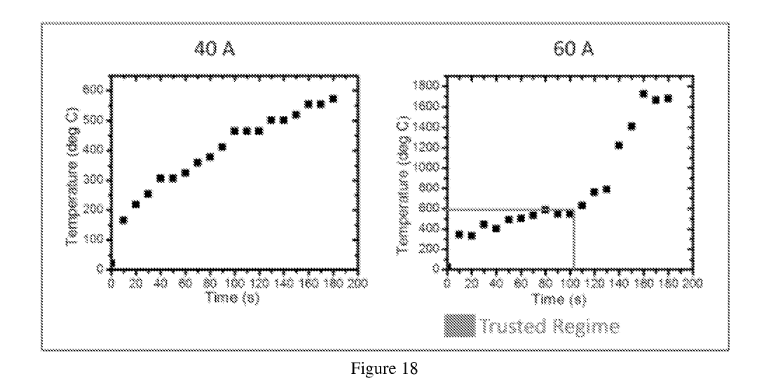

The current and the temperature of the foil can be compared via the resistance of the foil. A test apparatus from a piece of 430 stainless steel foil inside of a Lindberg furnace was used. The temperature was monitored by a K type thermal couple. The resistance of the foil was taken at a 10 degree Celsius interval between 20° C. and 500° C. The normalized change in resistance (normalized by the resistance at 20.4° C.) was plotted versus the change in temperature to extract the slope, or the temperature coefficient of resistivity, of the stainless steel. The results are shown in FIG. 17.

Finding the temperature coefficient of resistivity enabled the temperature profile at the surface to be determined. The temperature profile at the surface was examined for 40 A and 60 A. The data is provided in FIG. 18.

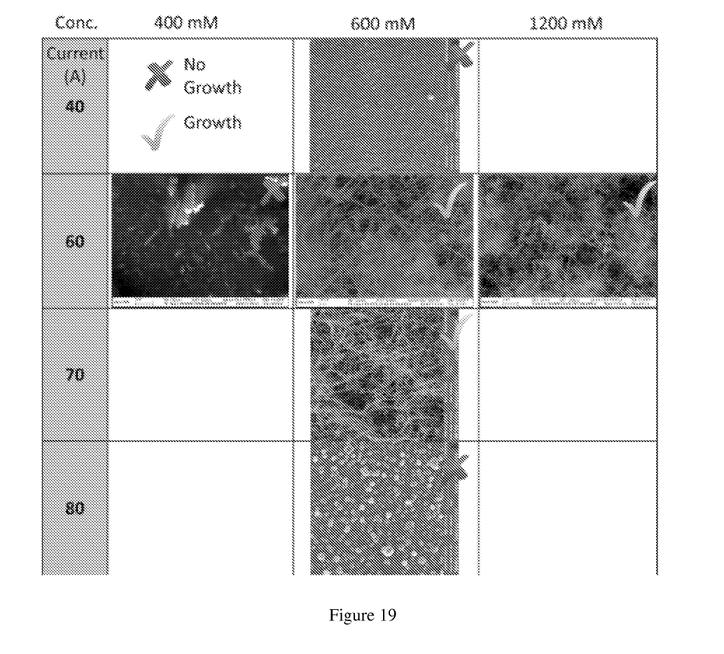

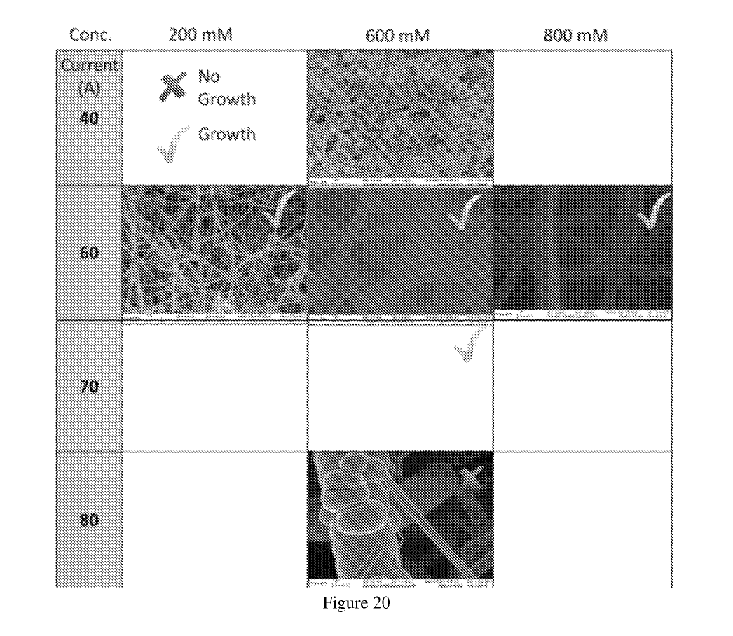

Investigation into current and phenylsilane concentration was performed. The data in FIG. 19 demonstrates that temperature may be an important aspect to nanowires growth. Growth is observed at 60 A and 70 A. However, notable changes occurred on the surface of 40 A and 80 A. Notably, the Si nanowires produced at 60 A may have desirable parameters and properties. A similar set of experiments was performed for diphenylgermane, as seen in FIG. 20.

A set of identical experiments was performed with varying annealing times at 600 mM phenylsilane in squalene and 60 A, conditions shown above to produce nanowires. FIG. 21 shows the results of the time study of Si nanowire growth. It is observed that a few short wires are produced by the 60 s mark. By 180 s, a consistent film of Si nanowires is produced. At the 240 s mark the film has grown thicker. A similar experiment was performed for Ge using 600 mM diphenylgermane and 60 A current, as seen in FIG. 22. Product nanowires were observed sooner in the gas environment over the liquid environment.

Inductive heating is a viable alternative to produce nanowires. Nanowires can be grown from electrodeposited films or thermally evaporated Cu films. The process of electrodepostion may be improved by adding sulfuric acid to the copper sulfate solution.

Although the present disclosure has been described with respect to one or more particular embodiments, it will be understood that other embodiments of the present disclosure may be made without departing from the spirit and scope of the present disclosure. Hence, the present disclosure is deemed limited only by the appended claims and the reasonable interpretation thereof.

What is claimed is:

1. A method comprising:
exposing a flexible substrate to a Group IV precursor during a roll-to-roll process; and
heating the substrate during the exposing such that a plurality of Group IV nanowires grow on a surface of the substrate, wherein the substrate is resistively heated by passing a current through the substrate or inductively heated by inducing a current in the substrate.

2. The method of claim 1, wherein growth of the Group IV nanowires is carried out such that a pattern of the Group IV nanowires on less than an entirety of the surface of the substrate is produced.

3. The method of claim 1, wherein the substrate is at a temperature from 200° C. to 800° C. during the heating.

4. The method of claim 1, further comprising functionalizing the Group IV nanowires.

5. The method of claim 1, further comprising applying a metal coating to the Group IV nanowires.

6. The method of claim 1, further comprising resistively heating or inductively heating the substrate after the exposing thereby drying the substrate.

7. The method of claim 1, further comprising providing secondary convective heating around the substrate during the exposing.

8. The method of claim 1, wherein the exposing occurs at substantially atmospheric pressure.

9. An article comprising:
a flexible substrate; and
a plurality of Group IV nanowires disposed on a surface of the substrate, wherein the Group IV nanowires on the surface have a surface loading greater than 10 mg/cm².

10. The article of claim 9, wherein the Group IV nanowires are composed of Si, Ge, or a combination thereof.

11. The article of claim 9, wherein the Group IV nanowires are arranged in a pattern on less than an entirety of the surface.

12. The article of claim 9, wherein the Group IV nanowires are between 5 nm and 100 nm in a first dimension and are greater than 100 μm in a second dimension perpendicular to the first dimension.

13. The article of claim 9, wherein the substrate comprises a metal, a ceramic, a polymer, a fiber, or a composite.

14. The article of claim 9, wherein the substrate comprises a sheet, a foil, or a wire.

15. The article of claim 9, wherein the surface of the substrate is a metal selected from the group consisting of Cu, Ni, Cr, Mn, Ti, Fe, Co, Pd, and Pt.

16. The article of claim 9, wherein the Group IV nanowires are functionalized.

17. The article of claim 9, further comprising a metal coating applied to the Group IV nanowires.

18. The article of claim 9, wherein the substrate comprises a growth layer disposed on a heating layer, wherein the growth layer comprises copper and wherein the heating layer comprises one of Nichrome or magnetic stainless steel.

19. The article of claim 9, further comprising a metal layer disposed on the plurality of Group IV nanowires and a second plurality of Group IV nanowires disposed on the metal layer.

20. An apparatus comprising:
a reactor chamber configured for roll-to-roll processing of a flexible substrate;
a Group IV precursor supply connected to the reactor chamber; and
a heating system configured to resistively heat by passing a current through the substrate or inductively heat by inducing a current in the substrate.
